(19) United States
(12) Patent Application Publication
(10) Pub. No.: US 2023/0127206 A1
(43) Pub. Date: Apr. 27, 2023

(54) REGULATED SUPPLY FOR IMPROVED SINGLE-ENDED CHOPPING PERFORMANCE

(71) Applicant: TEXAS INSTRUMENTS INCORPORATED, Dallas, TX (US)

(72) Inventor: Ryan LIND, Knoxville, TN (US)

(21) Appl. No.: 17/828,467

(22) Filed: May 31, 2022

Related U.S. Application Data
(60) Provisional application No. 63/272,312, filed on Oct. 27, 2021.

(51) Int. Cl. H03F 3/45; H03F 1/02; H03F 3/393

(52) U.S. Cl. CPC H03F 3/45183; H03F 3/45475; H03F 1/0227; H03F 3/393; H03F 2200/84; H03F 2203/45212; H03F 2200/555

(57) ABSTRACT

A circuit includes a single-ended amplifier having first and second transistors and an amplifier output. The first transistor has a first control input and first and second current terminals. The second transistor has a second control input and third and fourth current terminals. The first and third current terminals are coupled to an adaptively regulated voltage terminal. The circuit also includes a chopper circuit coupled to the amplifier output and to the first and second transistors. A voltage tracking circuit has a voltage tracking circuit input and a voltage tracking circuit output. The voltage tracking circuit input is coupled to the amplifier output, and the voltage tracking circuit output is coupled to the adaptively regulated voltage terminal. The voltage tracking circuit is configured to adaptively vary a voltage on the regulated voltage terminal based on the amplifier output.

### CROSS-REFERENCE TO RELATED APPLICATIONS

This application claims priority to U.S. Provisional Application No. 63/272,312, filed Oct. 27, 2021, which is hereby incorporated by reference.

### BACKGROUND

Many different types of circuits have offset voltages that effect the accuracy of their output signals. One technique to reduce the effects of an offset voltage is to trim the circuit. Trimming involves testing the circuit to determine how to adjust certain internal parameters within the circuit. Trimming is time-consuming and expensive. Another technique to reduce the effects of an offset voltage is the use of a chopper circuit. A chopper circuit includes switches operated at a relatively high frequency to, for example, swap polarities of an input signal to, and an output signal from, the circuit. While chopping generally avoids the need for trimming, chopping removes some, but not necessarily all of the offset. The inability of a chopping technique to remove all of the offset is particularly problematic for differential input/single-ended output circuits due to bias voltage settling.

### SUMMARY

In one example, a circuit includes a single-ended amplifier having first and second transistors and an amplifier output. The first transistor has a first control input and first and second current terminals. The second transistor has a second control input and third and fourth current terminals. The first and third current terminals are coupled to an adaptively regulated voltage terminal. The circuit also includes a chopper circuit coupled to the amplifier output and to the first and second transistors. A voltage tracking circuit has a voltage tracking circuit input and a voltage tracking circuit output. The voltage tracking circuit input is coupled to the amplifier output, and the voltage tracking circuit output is coupled to the adaptively regulated voltage terminal. The voltage tracking circuit is configured to adaptively vary a voltage on the regulated voltage terminal based on the amplifier output.

### BRIEF DESCRIPTION OF THE DRAWINGS

FIG. 1 is a block diagram of a voltage converter including an amplifier in accordance with a described example.

FIG. 2 is a circuit depicting an example implementation of the amplifier of FIG. 1 in accordance with an example.

FIG. 3 is a circuit depicting another example implementation of the amplifier of FIG. 1 and includes a voltage tracking circuit in accordance with an example.

FIG. 4 is a circuit depicting yet another example implementation of the amplifier of FIG. 1 and also includes a voltage tracking circuit in accordance with an example.

### DETAILED DESCRIPTION

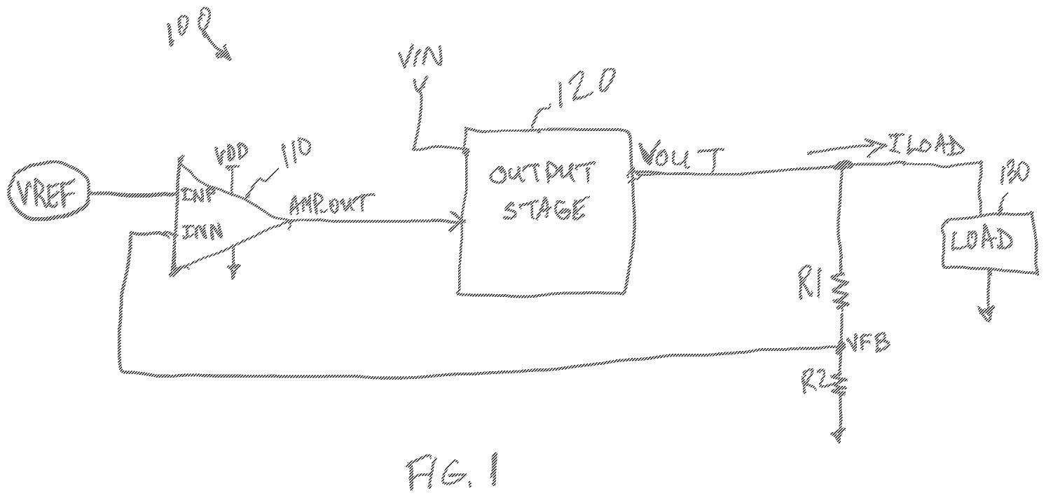

FIG. 1 shows an example of a system 100 which includes an amplifier 110 coupled to an output stage 120. The system 100 may be a voltage converter that converts an input direct current (DC) voltage (VIN) to an output DC voltage (VOUT) at an appropriate magnitude to power a load 130. The voltage converter includes a voltage divider including resistors R1 and R2 coupled in series between VOUT and ground. The voltage on the connection point between resistors R1 and R2 is a feedback voltage (VFB) that is a function of VOUT (e.g., VFB=VOUT(R/(R1+R2).

The amplifier 110 in the example of FIG. 1 has a positive input (INP) and a negative input (INN). The INN input is coupled to VFB, and the INP input is coupled to a reference voltage source (VREF). Amplifier 110 amplifies the difference between VREF and VFB to produce an output signal (AMP_OUT). The output signal AMP_OUT indicates whether, and by how much, VFB is different than VREF, and is provided as a control input to the output stage 120. The output stage 120 responds to a change in AMP_OUT by causing the current to the load (ILOAD) to increase or decrease to thereby cause VOUT to increase or decrease. The amplifier 110 and output stage 120 form a control loop to cause VOUT to be maintained at a level by which VOUT (through its proxy VFB) is approximately equal to VREF.

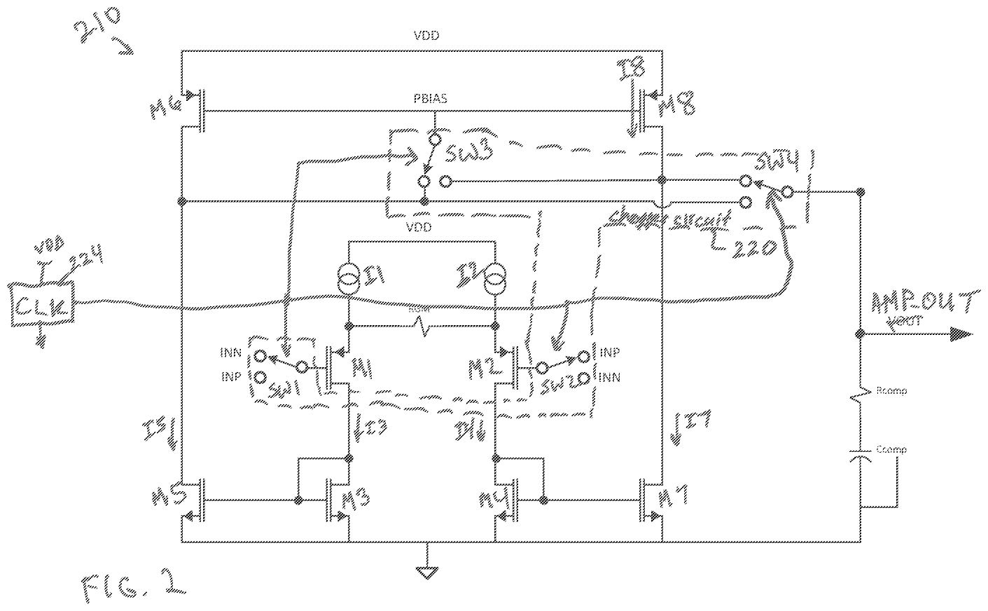

FIG. 2 is a schematic illustrating an example implementation of an amplifier 210, which can be used to implement amplifier 110 in FIG. 1. The example amplifier 210 of FIG. 2 includes transistors M1, M2, M3, M4, M5, M6, M7, and M8, current source circuits I1 and 12, and resistor RGM. The amplifier 210 also includes or is coupled to a chopper circuit 220, which includes switches SW1, SW2, SW3, and SW4. Transistors M1, M2, M6, and M8 are p-channel field effect transistors (PFETs), and transistors M3, M4, M5, and M7 are n-channel field effect transistors (NFETs).

Current source circuit I1 (“I1” refers both to the current source circuit and the magnitude of the current produced therefrom) is coupled between the power supply terminal VDD and the source of transistor M1. Current source circuit I2 (“I2” refers both to the current source circuit and the magnitude of the current produced therefrom) is coupled between the power supply terminal VDD and the source of transistor M2. Resistor RGM is coupled between the sources of transistors M1 and M2. The drains of transistors M1 and M2 are coupled to the drains of transistors M3 and M4, respectively. Transistors M1 and M2 are a differential input pair of transistors, whose use as the inputs to the amplifier 210 is described below.

The drain and gate of transistor M3 are coupled together, as are the drain and gate of transistor M4. The sources of transistors M3, M4, M5, and M7 are coupled together. The gates of transistors M3 and M5 are coupled together, as are the gates of transistors M4 and M7. Transistors M3 and M5 are configured to operate as a current mirror to mirror the current I3 through transistors M1 and M3 as current I5 through transistor M5. The current mirror ratio between transistors M3 and M5 may be 1:1 which means the magnitude of current I5 is the same as the magnitude of current I3. In other embodiments, the current mirror ratio may be other than 1:1. Similarly, transistors M4 and M7 are configured to operate as a current mirror to mirror the current I4 through transistors M2 and M4 as current I7 through transistor M7. The current mirror ratio between transistors M4 and M7 may be 1:1 or other than 1:1. In one embodiment, the current mirror ratios of the current mirrors comprising transistors M3/M7 and M4/M7 are the same.

The sources of transistors M6 and M8 are coupled together and to VDD. The gates of transistors M6 and M8 are coupled together. The drain of transistor M6 is coupled to the drain of transistor M5, and the drain of transistor M8 is coupled to the drain of transistor M7.

Switch SW1 of the chopper circuit includes three switch terminals. One switch terminal is coupled to the gate of transistor M1, and the other two switch terminals are coupled to amplifier inputs INN and INP, as shown. With the switch SW1 in the connectivity shown, amplifier input INN is coupled to the gate of transistor M1. In the other connectivity state, amplifier input INP would be coupled to the gate of transistor M1. Accordingly, the gate of transistor M1 receives the voltage from either the amplifier input INN or INP depending on the state of the switch.

Switch SW2 similarly couples amplifier inputs INP and INN to the gate of transistor M2. One switch terminal of switch SW2 is coupled to the gate of transistor M2, and the other two switch terminals are coupled to amplifier inputs INP and INN, as shown. With the switch SW2 in the connectivity shown, amplifier input INP is coupled to the gate of transistor M2. In the other connectivity state, amplifier input INN would be coupled to the gate of transistor M2. Accordingly, the switches SW1 and SW2 are operated to be in one of two states. In one state, input INN is coupled to the gate of transistor M1, and input INP is coupled to the gate of transistor M2. In the other state, input INP is coupled to the gate of transistor M1, and input INN is coupled to the gate of transistor M2. A clock generator circuit 224 may be included to provide the control signals to the switches SW1 and SW2. Switches SW1 and SW2 chop the differential input signal INP/INN to the differential input pair of transistors M1 and M2 to reduce the offset that may exist between transistors M1 and M2.

Switches SW3 and SW4 are also controlled by the clock circuit 224 to chop the output of the amplifier 210. One switch terminal of switch SW3 is coupled to the gates of transistors M6 and M8, while other switch terminals of switch SW3 are coupled to the drains of transistors M6 and M8, as shown. One switch terminal of switch SW4 is coupled to and provides the output voltage AMP_OUT from the amplifier 210. Another switch terminal of switch SW4 is coupled to the drain of transistor M8 (and thus to one switch terminal of switch SW3 as shown), while the third switch terminal of switch SW4 is coupled to the drain of transistor M6 (and thus to a switch terminal of switch SW3).

While in the connectivity state shown in FIG. 2, the gate and drain of transistor M6 are coupled together and the amplifier output, AMP_OUT is the voltage on the drain of transistor M8. With the gate and drain of transistor M6 coupled together, transistors M6 and M8 are configured as a current mirror by which the current through transistor M6 (which is the current, I5, through transistor M5) is mirrored through transistor M8. In the opposite connectivity states for switches SW3 and SW4, the gate and drain of transistor M8 are coupled together and the amplifier output, AMP_OUT would be the voltage on the drain of transistor M6. In this latter state, transistors M6 and M8 are still configured as a current mirror but for which the current through transistor M8 (which is the current, I7, through transistor M7) is mirrored through transistor M6.

During operation and assuming the four switches SW1-SW4 of the chopper circuit 220 are in the connection states shown in FIG. 2, if the voltage on input INP is larger than the voltage on input INN, the gate voltage of PFET M1 will be smaller than the gate voltage of transistor M2, so the source-to-gate voltage (Vsg) of transistor M1 will be larger than the Vsg of transistor M2. With the Vsg of transistor M1 being larger than that of transistor M2, current I3 will be larger than current I4. Larger current I3 is mirrored as current IS, and smaller current I4 is mirrored as current I7. Accordingly, current I5 is larger than current I7 (assuming 1:1 current mirror ratios).

The gate and drain of transistor M6 are coupled together (SW3 is in the state shown in FIG. 2). Current I5 flows through transistor M6. As described above, transistors M6 and M8 comprise a current mirror in which the current through transistor M6 is mirrored through transistor M8 as current I8. Current I8 is larger than current I7. With switch SW4 in the configuration shown in FIG. 2, current I8 divides between transistor M7 and the output of the amplifier. That portion of current I8 in excess of current I7 flows to the output of the amplifier 210 and through resistor Rcomp and capacitor Ccomp. The magnitude of AMP_OUT is a function of the difference between currents I8 and I7 and is the sum of the voltage across capacitor Ccomp and resistor Rcomp.

When the four switches change state from that shown in FIG. 2, the operation of the amplifier is largely the same as that described above, but with current I4 and I7 being larger than current I3 and I5. The gate and drain of transistor M8 are coupled together so the larger current I8 through transistor M8 (larger than 13 or 15) is mirrored through transistor M6. The current through transistor M6 is larger than current I5, and the excess current flows through switch SW4 to the output (and resistor Rrcomp and capacitor Ccomp).

The voltage on the gates of transistors M6 and M8 is labeled ‘BIAS.’ PBIAS is VDD minus the Vsg of transistor M6 (M8) and remains fairly constant despite the chopping circuit 220 repeatedly changing state. With switch S3 in the connection state shown in FIG. 2, the voltage on the drain of transistor M6 is PBIAS, which is VDD-Vsg(M6). The voltage on the drain of transistor M8 is AMP_OUT, which is a function of the differential input voltage (INP-INN). In the opposite connection state for switches SW3 and SW4, the voltage on the drain of transistor M8 is PBIAS (VDD-Vsg(M8)), and the voltage on the drain of transistor M6 is AMP_OUT. Depending on the differential input voltage, the difference between AMP_OUT and PBIAS can be fairly substantial. As the chopping circuit 220 repeatedly changes switch states, the voltage difference between the drains of transistors M6 and M8 can be large enough to cause an offset voltage. The offset is due to the constant resettling of the voltage on the drains of transistors M6 and M8 to AMP_OUT and PBIAS. This resettling is in the same polarity direction which adds an offset current component to the output which then presents itself as an offset voltage on Ccomp/Rcomp.

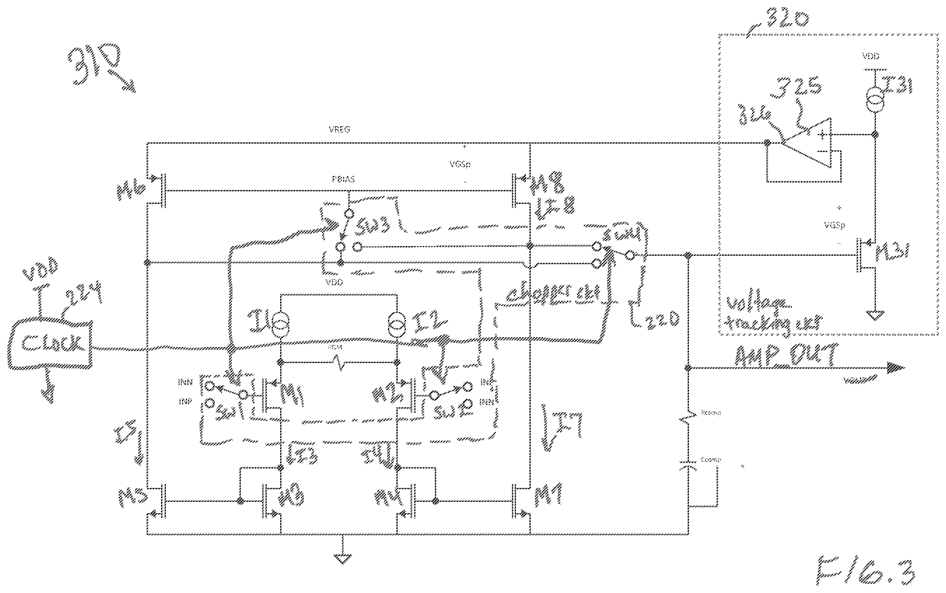

FIG. 3 shows an example circuit implementation of an amplifier 310 which may be used to implement amplifier 110 of FIG. 1. Amplifier 310 is similar to amplifier 210, but amplifier 310 includes a voltage tracking circuit 320 not included as part of amplifier 210. As for the example amplifier 210, amplifier 310 in FIG. 3 includes transistors M1, M2, M3, M4, M5, M6, M7, and M8, current source circuits I1 and 12, and resistor RGM. The amplifier 310 also includes or is coupled to a chopper circuit 220, which includes switches SW1, SW2, SW3, and SW4.

Current source circuit I1 is coupled between the power supply terminal VDD and the source of transistor M1. Current source circuit I2 is coupled between the power supply terminal VDD and the source of transistor M2. Resistor RGM is coupled between the sources of transistors M1 and M2. The drains of transistors M1 and M2 are coupled to the drains of transistors M3 and M4, respectively. Transistors M1 and M2 are a differential input pair of transistors. The drain and gate of transistor M3 are coupled together, as are the drain and gate of transistor M4. The sources of transistors M3, M4, M5, and M7 are coupled together. The gates of transistors M3 and M5 are coupled together, as are the gates of transistors M4 and M7. As described above, transistors M3 and M5 are configured to operate as a current mirror to mirror the current I3 through transistors M1 and M3 as current I5 through transistor M5. Similarly, transistors M4 and M7 are configured to operate as a current mirror to mirror the current I4 through transistors M2 and M4 as current I7 through transistor M7.

The sources of transistors M6 and M8 are coupled together at a voltage terminal labeled ‘VREG’ (rather than VDD as for amplifier 210). The gates of transistors M6 and M8 are coupled together. The drain of transistor M6 is coupled to the drain of transistor M5, and the drain of transistor M8 is coupled to the drain of transistor M7.

Switch SW1 of the chopper circuit 220 switches the gate of transistor M1 to either input INN or input INP, as described above. Similarly, switch SW2 switches the gate of transistor M2 to either input INP or input INN. Accordingly, the switches SW1 and SW2 are operated to be in one of two states. In one state, input INN is coupled to the gate of transistor M1 and input INP is coupled to the gate of transistor M2. In the other state, input INP is coupled to the gate of transistor M1 and input INN is coupled to the gate of transistor M2. A clock generator circuit 224 may be included to provide the control signals to the switches SW1 and SW2. Switches SW1 and SW2 chop the differential input signal to the differential input pair of transistors M1 and M2 to reduce the offset that may exist between transistors M1 and M2.

Also, as described above, switches SW3 and SW4 are controlled by the clock circuit 224 to chop the output of the amplifier 210. One switch terminal of switch SW3 is coupled to the gates of transistors M6 and M8, while other switch terminals of switch SW3 are coupled to the drains of transistors M6 and M8, as shown. One switch terminal of switch SW4 is coupled to and provides the output voltage AMP_OUT from the amplifier 210. Another switch terminal of switch SW4 is coupled to the drain of transistor M8 (and thus to one switch terminal of switch SW3 as shown), while the third switch terminal of switch SW4 is coupled to the drain of transistor M6 (and thus to a switch terminal of switch SW3).

The voltage tracking circuit 320 of FIG. 3 solves the offset voltage problem noted above regarding FIG. 2 in which, because the output voltage AMP_OUT may be substantially different than the (VDD-Vsg(M6)), an offset voltage is generated. As described herein, the voltage tracking circuit is configured to adaptively vary a voltage on the regulated voltage terminal (VREG) based on the amplifier output, AMP_OUT.

The voltage tracking circuit 320 includes a transistor M31, a current source circuit I31, and a buffer 325. The buffer 325 is configured for unity gain (its negative input (−) is coupled to its output). The output 326 from buffer 325 is coupled to the voltage terminal VREG. The current source circuit I31 is coupled to the source of transistor M31 (which is a PFET in this example) and provides the bias current for transistor M31. In one example, the magnitude of I1, I2, and I31 are approximately to each other. The source of transistor M31 is also coupled to the positive input (+) of buffer 325.

Switch SW4 is coupled to the gate of transistor M31, so the amplifier output signal, AMP_OUT, is coupled to the gate of transistor M31. The voltage on the source of transistor M31 is the magnitude of the Vsg of transistor M31 greater than its gate voltage. Accordingly, the voltage on the positive input of buffer 325 is (AMP_OUT+Vsg(M31)). In turn, VREG also is (AMP_OUT+Vsg(M31)). This means that VREG adaptively changes to remain 1*Vsg above AMP_OUT. Further, the PBIAS voltage is 1*Vsg smaller than VREG, so the voltage of PBIAS is approximately equal AMP_OUT.

For whichever of transistors M6 or M8 is configured through switch SW3 as a diode-connected transistor (gate coupled to drain), the voltage on the drain of that transistor is approximately equal to AMP_OUT. For the other transistor (the transistor not configured as a diode-connected transistor), the voltage on its drain also is approximately equal to AMP_OUT. Whereas in the example of FIG. 2, the voltage on the sources of transistors M6 and M8 were connected to VDD, which is a fixed voltage, the tracking circuit 320 of FIG. 3 adaptively changes the voltage of VREG (sources of M6 and M8) to remain approximately equal to (AMP_OUT+Vsg(M31)). The Vsg of transistor M31 is approximately equal to the Vsg of transistors M6 and M8 (when not configured as a diode-connected transistor). In this way, the voltage tracking circuit 320 dramatically removes the offset voltage otherwise present for amplifier 210 in FIG. 2.

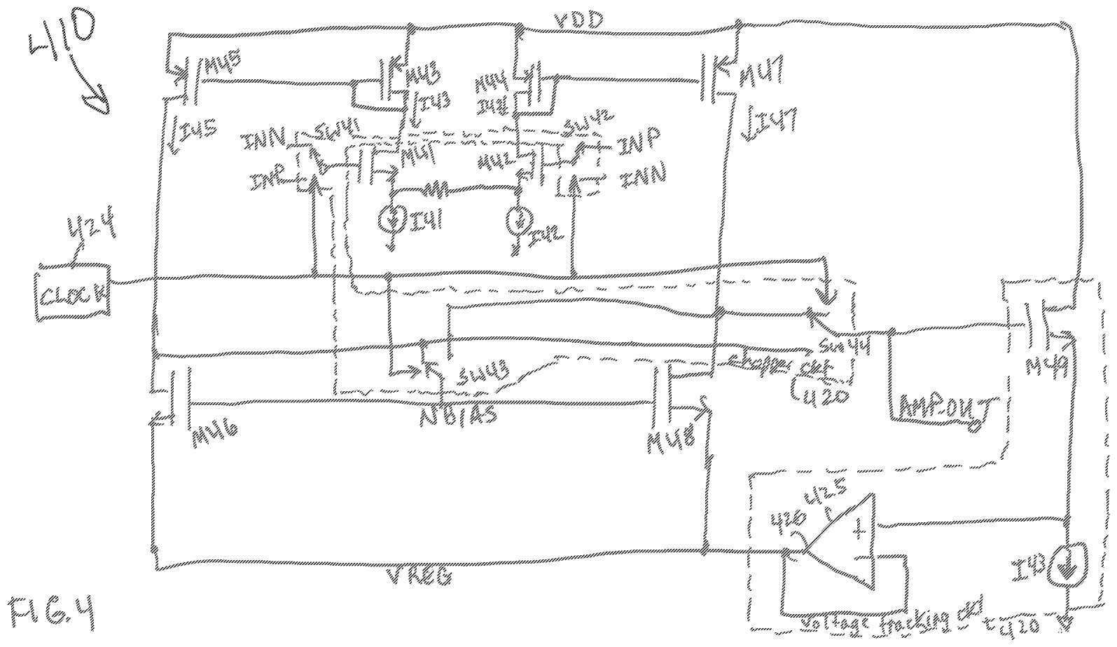

FIG. 4 is an example of an amplifier 410 which may be used to implement amplifier 110 of FIG. 1. The amplifier 410 of FIG. 4 is functionally equivalent to amplifier 310 of FIG. 3, but with NFETs replaced with PFETs and with PFETs replaced with NFETs. Amplifier 410 in FIG. 3 includes transistors M41, M42, M43, M44, M45, M46, M47, and M48, current source circuits I41 and I42, and resistor RGM. Transistors M41, M42, M46, and M48 are NFETS, and transistors M43, M44, M55, and M47 are PFETs. The amplifier 410 also includes or is coupled to a chopper circuit 420, which includes switches SW41, SW42, SW43, and SW44. A voltage tracking circuit 420 is included as well for much the same function as that performed by the voltage tracking circuit 320 in FIG. 3.

Current source circuit I41 is coupled between ground and the source of transistor M41. Current source circuit I42 is coupled between ground and the source of transistor M42. Resistor RGM is coupled between the sources of transistors M41 and M42. The drains of transistors M41 and M42 are coupled to the drains of transistors M43 and M44, respectively. Transistors M41 and M42 are a differential input pair of transistors. The drain and gate of transistor M43 are coupled together, as are the drain and gate of transistor M44. The sources of transistors M43, M44, M45, and M47 are coupled together and to VDD. The gates of transistors M43 and M45 are coupled together, as are the gates of transistors M44 and M47. Transistors M43 and M45 are configured to operate as a current mirror to mirror the current I43 through transistors M41 and M43 as current I45 through transistor M45. Similarly, transistors M44 and M47 are configured to operate as a current mirror to mirror the current I44 through transistors M42 and M44 as current I47 through transistor M47.

The sources of transistors M46 and M48 are coupled together at the voltage terminal, VREG. The gates of transistors M46 and M48 are coupled together and receive a voltage labeled as NBIAS. The drain of transistor M46 is coupled to the drain of transistor M45, and the drain of transistor M48 is coupled to the drain of transistor M47.

Switch SW41 of the chopper circuit 420 switches the gate of transistor M41 to either input INN or input INP, as described above. Similarly, switch SW42 switches the gate of transistor M42 to either input INP or input INN. Accordingly, the switches SW41 and SW42 are operated to be in one of two states. In one state, input INN is coupled to the gate of transistor M41 and input INP is coupled to the gate of transistor M42. In the other state, input INP is coupled to the gate of transistor M41, and input INN is coupled to the gate of transistor M42. A clock generator circuit 424 may be included to provide the control signals to the switches SW41 and SW42. Switches SW41 and SW42 chop the differential input signal to the differential input pair of transistors M41 and M42 to reduce the offset that may exist between transistors M41 and M42.

Also as described above, switches SW43 and SW44 are also controlled by the clock circuit 424 to chop the output of the amplifier 410. One switch terminal of switch SW43 is coupled to the gates of transistors M46 and M48, while other switch terminals of switch SW43 are coupled to the drains of transistors M46 and M48, as shown. One switch terminal of switch SW44 is coupled to and provides the output voltage AMP_OUT from the amplifier 410. Another switch terminal of switch SW44 is coupled to the drain of transistor M48 (and thus to one switch terminal of switch SW43 as shown), while the third switch terminal of switch SW44 is coupled to the drain of transistor M46 (and thus to a switch terminal of switch SW43).

The voltage tracking circuit 420 of FIG. 4 functions similar to that described above regarding voltage tracking circuit 320 for amplifier 310 to reduce the offset voltage noted above regarding FIG. 2. Voltage tracking circuit 420 includes a transistor M49, a current source circuit I43, and a buffer 425. The buffer 425 is configured for unity gain (its negative input (−) is coupled to its output). The output 426 from buffer 425 is coupled to the voltage terminal VREG. The current source circuit I43 is coupled to the source of transistor M49 (which is an NFET in this example) and provides the bias current for transistor M49. The source of transistor M49 is also coupled to the positive input (+) of buffer 425.

Switch SW44 is coupled to the gate of transistor M49, so the amplifier output signal, AMP_OUT, is coupled to the gate of transistor M49. The voltage on the source of transistor M49 is the magnitude of the gate-to-source voltage (Vgs) of transistor M49 smaller than its gate voltage. Accordingly, the voltage on the positive input of buffer 425 is (AMP_OUT−Vgs(M49)). In turn, VREG also is (AMP_OUT−Vgs(M49)). This means that VREG adaptively changes to remain 1*Vsg below AMP_OUT. Further, the voltage of NBIAS is 1*Vgs greater than VREG, so the voltage of NBIAS is approximately equal AMP_OUT regardless of the level of AMP_OUT.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead. For example, a p-channel field effect transistor (“PFET”) may be used in place of an n-channel field effect transistor (NFET) with little or no changes to the circuit. Furthermore, other types of transistors may be used (such as bipolar junction transistors (BJTs)). A transistor has a control input and a pair of current terminals. The control input for a FET is the gate, and the current terminals are the source and drain. The control input for a BJT is the base, and the current terminals are the collector and emitter.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means +/−10 percent of the stated parameter.

Modifications are possible in the described embodiments, and other embodiments are possible, within the scope of the claims.

What is claimed is:

1. A circuit, comprising:
a single-ended amplifier having first and second transistors and an amplifier output, the first transistor having a first control input and first and second current terminals, the second transistor having a second control input and third and fourth current terminals, and the first and third current terminals are coupled to an adaptively regulated voltage terminal;
a chopper circuit coupled to the amplifier output and to the first and second transistors; and
a voltage tracking circuit having a voltage tracking circuit input and a voltage tracking circuit output, the voltage tracking circuit input coupled to the amplifier output, and the voltage tracking circuit output coupled to the adaptively regulated voltage terminal, the voltage tracking circuit configured to adaptively vary a voltage on the regulated voltage terminal based on the amplifier output.

2. The circuit of claim 1, wherein the voltage tracking circuit comprises:
a third transistor having a third control input and fifth and sixth current terminals, the third control input coupled to the chopping circuit and to the amplifier output; and
a buffer having a buffer input and a buffer output, the buffer input coupled to the fifth current terminal, the buffer output is the voltage tracking circuit output and is coupled to the regulated voltage terminal.

3. The circuit of claim 2, further comprising a current source circuit coupled to the fifth current terminal.

4. The circuit of claim 2, wherein the chopper circuit comprises:
a first switch having first, second, and third switch terminals, the first switch terminal coupled to the first and second control inputs, the second switch terminal coupled to the second current terminal, and the third switch terminal coupled to the fourth current terminal; and
a second switch having fourth, fifth, and sixth switch terminals, the fourth switch terminal coupled to the amplifier output and to the third control input, the fifth switch terminal coupled to the second current terminal, and the sixth switch terminal coupled to the fourth current terminal.

5. The circuit of claim 2, wherein the buffer is a unity gain buffer.

6. The circuit of claim 1, wherein the voltage tracking circuit is configured to vary the voltage on the adaptively regulated voltage terminal to be approximately a sum of the voltage on the amplifier output and a voltage that is a voltage difference between the first control input and the first current terminal.

7. The circuit of claim 1, wherein the voltage tracking circuit is configured to vary the voltage on the adaptively regulated voltage terminal to be approximately a difference of the voltage on the amplifier output and a voltage that is a voltage difference between the first control input and the first current terminal.

8. The circuit of claim 1, wherein the first control input is coupled to the second control input.

9. An amplifier, comprising:
a first input transistor;
a second input transistor;
a first current mirror coupled to the first input transistor;
a second current mirror coupled to the second input transistor;
a third transistor having a first control input and first and second current terminals, the second current terminal coupled to the first current mirror;
a fourth transistor having a second control input and third and fourth current terminals, the fourth control input coupled to the third control input, and the fourth current terminal coupled to the second current mirror;
a first switch having first, second, and third switch terminals, the first switch terminal coupled to the third and fourth control inputs, the second switch terminal coupled to the drain of the third transistor, and the third switch terminal coupled to the drain of the fourth transistor;
a second switch having fourth, fifth, and sixth switch terminals, the fourth switch terminal coupled to an output of the amplifier, the fifth switch terminal coupled to the second current terminal, and the sixth switch terminal coupled to the fourth current terminal; and
a voltage tracking circuit having a voltage tracking circuit input and a voltage tracking circuit output, the voltage tracking circuit input coupled to the output of the amplifier, and the voltage tracking circuit output coupled to the first and third current terminals, herein the voltage tracking circuit is configured to generate a voltage on the first and third current terminals that is approximately equal to a sum or difference of the voltage on the output of the amplifier and a voltage difference between the first control input and the first current terminal.

10. The amplifier of claim 9, wherein the voltage tracking circuit comprises:
a fifth transistor having a third control input and fifth and sixth current terminals, the fifth control input coupled to the output of the amplifier; and
a buffer having a buffer input and a buffer output, the buffer input coupled to the fifth current terminal, the buffer output is the voltage tracking circuit output and is coupled to the first and third current terminals.

11. The amplifier of claim 10, further comprising a current source circuit coupled to the fifth current terminal.

12. The amplifier of claim 10, wherein the buffer is a unity gain buffer.

13. A voltage converter, comprising:
an output stage having an input voltage terminal, a control voltage input, and an output voltage terminal;
amplifier including:
first and second transistors and an amplifier output, the amplifier output coupled to the control voltage input, the first transistor having a first control input and first and second current terminals, the second transistor having a second control input and third and fourth current terminals, and the first and third current terminals are coupled to an adaptively regulated voltage terminal;
a chopper circuit coupled to the amplifier output and to the first and second transistors; and
a voltage tracking circuit having a voltage tracking circuit input and a voltage tracking circuit output, the voltage tracking circuit input coupled to the amplifier output, and the voltage tracking circuit output coupled to the adaptively regulated voltage terminal, the voltage tracking circuit configured to adaptively vary a voltage on the regulated voltage terminal based on a voltage of the amplifier output.

14. The voltage converter of claim 13, wherein the voltage tracking circuit comprises:
a third transistor having a third control input and fifth and sixth current terminals, the third control input coupled to the chopping circuit and to the amplifier output; and
a buffer having a buffer input and a buffer output, the buffer input coupled to the fifth current terminal, the buffer output is the voltage tracking circuit output and is coupled to the regulated voltage terminal.

15. The voltage converter of claim 14, further comprising a current source circuit coupled to the fifth current terminal.

16. The voltage converter of claim 14, wherein the chopper circuit comprises:
a first switch having first, second, and third switch terminals, the first switch terminal coupled to the first and second control inputs, the second switch terminal coupled to the second current terminal, and the third switch terminal coupled to the fourth current terminal; and
a second switch having fourth, fifth, and sixth switch terminals, the fourth switch terminal coupled to the amplifier output and to the third control input, the fifth switch terminal coupled to the second current terminal, and the sixth switch terminal coupled to the fourth current terminal.

17. The voltage converter of claim 14, wherein the buffer is a unity gain buffer.

18. The voltage converter of claim 13, wherein the voltage tracking circuit is configured to vary the voltage on the adaptively regulated voltage terminal to be approximately a sum of the voltage on the amplifier output and a voltage that is a voltage difference between the first control input and the first current terminal.

19. The voltage converter of claim 13, wherein the voltage tracking circuit is configured to vary the voltage on the adaptively regulated voltage terminal to be approximately a difference of the voltage on the amplifier output and a voltage that is a voltage difference between the first control input and the first current terminal.

20. The voltage converter of claim 13, wherein the first control input is coupled to the second control input.
